(19) United States
(12) Patent Application Publication
(10) Pub. No.: US 2024/0405118 A1
(43) Pub. Date: Dec. 5, 2024

(54) SEMICONDUCTOR DEVICE, SEMICONDUCTOR MODULE, AND ELECTRONIC APPARATUS

(71) Applicant: SONY SEMICONDUCTOR SOLUTIONS CORPORATION, KANAGAWA (JP)

(72) Inventor: KATSUHIKO TAKEUCHI, KANAGAWA (JP)

(21) Appl. No.: 18/262,726

(22) PCT Filed: Dec. 16, 2021
(86) PCT No.: PCT/JP2021/046629

§ 371 Date: Jul. 24, 2023

(30) Foreign Application Priority Data
Feb. 1, 2021 (JP) 2021-014618

(51) Int. Cl. H01L 29/778; H01L 29/20; H01L 29/66

(52) U.S. Cl. CPC H01L 29/7787; H01L 29/2003; H01L 29/66462

(57) ABSTRACT

A semiconductor device according to one embodiment of the present disclosure includes a low resistance material section and a low thermal resistance material section. The low resistance material section is in contact with a barrier layer, a channel layer, and a source electrode or a drain electrode, and includes a low resistance material having a lower resistance than the channel layer. The low thermal resistance material section is in contact with the channel layer and the buffer layer, and includes a low thermal resistance material having a lower thermal resistance than the channel layer.

### TECHNICAL FIELD

The present disclosure relates to a semiconductor device, a semiconductor module, and an electronic apparatus.

### BACKGROUND ART

In a fifth-generation mobile communication system (5G), use of a millimeter-wave-band signal is envisaged. In a millimeter wave band with a large spatial attenuation, a high power output is necessary, and a high output, high frequency semiconductor device is necessary. Examples of the high output, high frequency semiconductor device include a power amplifier and an RF switch (see, for example, Patent Literature 1).

### CITATION LIST

### Patent Literature

Patent Literature 1: Japanese Unexamined Patent Application Publication No. 2017-162958

### SUMMARY OF THE INVENTION

Incidentally, a high heat dissipation property is demanded for a high output, high frequency semiconductor device. Therefore, it is desirable to provide a semiconductor device having a high heat dissipation property, and a semiconductor module and an electronic apparatus including the semiconductor device.

A semiconductor device according to one embodiment of the present disclosure includes: a semiconductor layer; a channel layer including a semiconductor material different from that of the semiconductor layer, and stacked on the semiconductor layer; and a buffer layer formed between the semiconductor layer and the channel layer. The semiconductor device further includes: a barrier layer formed on the channel layer; a gate electrode formed on the barrier layer; and a source electrode and a drain electrode formed on the barrier layer at positions sandwiching the gate electrode. The semiconductor device further includes a low resistance material section and a low thermal resistance material section. The low resistance material section includes a low resistance material having a lower resistance than the channel layer, and is in contact with the barrier layer, the channel layer, and the source electrode or the drain electrode. The low thermal resistance material section includes a low thermal resistance material having a lower thermal resistance than the channel layer, and is in contact with the channel layer and the buffer layer.

A semiconductor module according to one embodiment of the present disclosure includes the above-described semiconductor device.

An electronic apparatus according to one embodiment of the present disclosure includes the above-described semiconductor device.

In the semiconductor device, the semiconductor module, and the electronic apparatus according to one embodiment of the present disclosure, the low thermal resistance material section is in contact with the buffer layer, formed between the semiconductor layer and the channel layer, and the channel layer. Thus, it is possible to discharge a heat generated in the channel layer to the semiconductor layer side through the low thermal resistance material section.

### BRIEF DESCRIPTION OF THE DRAWINGS

FIG. 1 is a diagram illustrating a cross-sectional configuration example of a semiconductor device according to an embodiment of the present disclosure.

FIG. 2 is a diagram illustrating a plan configuration example of the semiconductor device of FIG. 1.

FIG. 3 is a diagram illustrating an example of a manufacturing process of the semiconductor device of FIG. 1.

FIG. 4 is a diagram illustrating an example of a manufacturing process subsequent to FIG. 3.

FIG. 5 is a diagram illustrating an example of a manufacturing process subsequent to FIG. 4.

FIG. 6 is a diagram illustrating an example of a manufacturing process subsequent to FIG. 5.

FIG. 7 is a diagram illustrating an example of a manufacturing process subsequent to FIG. 6.

FIG. 8 is a diagram illustrating an example of a manufacturing process subsequent to FIG. 7.

FIG. 9 is a diagram illustrating an example of a manufacturing process subsequent to FIG. 8.

FIG. 10 is a diagram illustrating an example of a current path and a heat dissipation path of the semiconductor device of FIG. 1.

FIG. 11 is a diagram illustrating an example of a current path and a heat dissipation path of a semiconductor device according to a comparative example.

FIG. 12 is a diagram illustrating a modification example of a cross-sectional configuration of the semiconductor device of FIG. 1.

FIG. 13 is a diagram illustrating a plan configuration example of the semiconductor device of FIG. 12.

FIG. 14 is a diagram illustrating an example of a high-frequency module to which the semiconductor device of FIG. 1 is applied.

FIG. 15 is a diagram illustrating an example of a wireless communication device to which the semiconductor device of FIG. 1 is applied.

### MODES FOR CARRYING OUT THE INVENTION

Hereinafter, an embodiment for practicing the present disclosure is described in detail with reference to the drawings. The following description is a specific example of the present disclosure, and the present disclosure is not limited to the following embodiment. Moreover, the present disclosure does not limit the disposition, dimensions, dimension ratios, and the like of respective components illustrated in the drawings thereto. It is to be noted that description is given in the following order.
1. BACKGROUND
2. Embodiment (a semiconductor device)
3. Modification Examples (a semiconductor device)
4. Application Examples (a high-frequency module and a wireless communication device)

### 1. BACKGROUND

In a fifth-generation mobile communication system (5G), use of a millimeter-wave-band signal is envisaged. In a millimeter wave band with a large spatial attenuation, a high power output is necessary, and a high output, high frequency semiconductor device is necessary. Examples of the high output, high frequency semiconductor device include a power amplifier and an RF switch.

GaN has characteristics including a high breakdown voltage, a high temperature operation, and a high saturation-drift. A two-dimensional electron gas (2DEG) formed in a GaN-based heterojunction is characterized by a high mobility and a high-sheet electron density. These characteristics enable a high-speed, high-withstand voltage operation with low resistivity in a high electron mobility transistor (High Electron Mobility Transistor: HEMT) using the GaN-based heterojunction. Accordingly, the high electron mobility transistor using the GaN-based heterojunction is expected to be applied to a high-power, high-frequency semiconductor device. Hereinafter, an embodiment of a semiconductor device including a high electron mobility transistor using a GaN-based heterojunction will be described.

### 2. EMBODIMENT

### Configuration

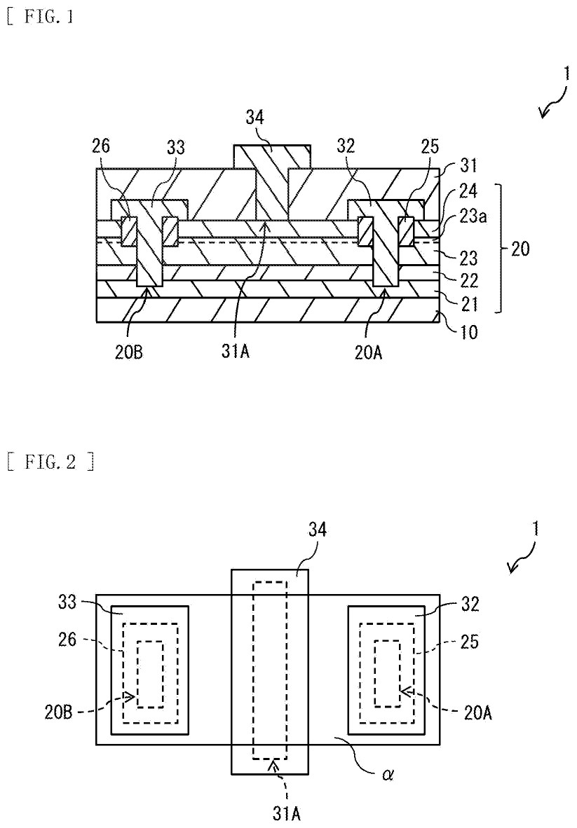

Next, a semiconductor device 1 according to an embodiment of the present disclosure will be described. FIG. 1 illustrates a cross-sectional configuration example of the semiconductor device 1 according to the present embodiment. The semiconductor device 1 includes a high electron mobility transistor using a heterojunction of Al_{1-x-y}GaₓIn_{y}N (0≤x<1, 0≤y<1)/GaN. FIG. 2 illustrates an example of a planar configuration of the semiconductor device 1 of FIG. 1. In FIG. 2, a region in which the high electron mobility transistor is formed is illustrated as an active region α. The periphery of the active region α is, for example, a non-active region whose resistance is increased by ion implantation of boron or the like.

The high electron mobility transistor is formed in a semiconductor stacked section 20 stacked on a substrate 10 having a lattice constant that is different from a lattice constant of GaN. The semiconductor stacked section 20 is an epitaxial crystal growth layer formed by performing an epitaxial crystal growth on the substrate 10. The substrate 10 corresponds to a specific example of a “semiconductor layer” of the present disclosure.

The semiconductor stacked section 20 includes a buffer layer 21 that controls the lattice constant at a position in contact with the substrate 10. The buffer layer 21 corresponds to a specific example of a “buffer layer” of the present disclosure. By providing the buffer layer 21, it is possible to improve a crystal state in a layer in which the high electron mobility transistor is formed in the semiconductor stacked section 20, and also to suppress a warpage of the substrate 10. Accordingly, the semiconductor device 1 has a configuration in which the high electron mobility transistor is formed on the substrate 10 via the buffer layer 21.

For example, as illustrated in FIG. 1, the semiconductor device 1 includes the substrate 10 and the semiconductor stacked section 20 stacked on the substrate 10. The semiconductor stacked section 20 has, for example, a configuration in which the buffer layer 21, a back barrier layer 22, a channel layer 23, and a barrier layer 24 are stacked in this order from the substrate 10 side. The back barrier layer 22 corresponds to a specific example of a “back barrier layer” of the present disclosure. The channel layer 23 corresponds to a specific example of a “channel layer” of the present disclosure. The barrier layer 24 corresponds to a specific example of a “barrier layer” of the present disclosure.

The substrate 10 includes, for example, Si, SiC, sapphire, or the like. A compound semiconductor used for the substrate 10 corresponds to a specific example of a “first compound semiconductor” of the present disclosure. The buffer layer 21 is configured by, for example, a compound semiconductor such as AlN, AlGaN, or GaN. The buffer layer 21 does not necessarily have to be a single layer, and may have a configuration in which at least two types of layers among an AlN layer, an AlGaN layer, and a GaN layer, for example, are stacked. In a case where the buffer layer 21 is configured by a ternary system (AlGaN), the buffer layer 21 may have a configuration in which a composition is gradually changed in a thickness direction.

The back barrier layer 22 is formed between the buffer layer 21 and the channel layer 23. The back barrier layer 22 includes a compound semiconductor material having an action of lifting an energy band of a portion, within the channel layer 23, on the back barrier layer 22 side. Examples of such a compound semiconductor material include a compound semiconductor material having a wider bandgap than the channel layer 23 (for example, Al_{1-a-b}GaₐIn_{b}N (0≤a<1, 0≤b<1)). The back barrier layer 22 may include an undoped compound semiconductor material. The back barrier layer 22 does not necessarily have to a single layer, and may have a configuration in which a plurality of Al_{1-a-b}GaₐIn_{b}N layers that are different from each other are stacked. In a case where the back barrier layer 22 is configured by a ternary system (AlInN) or a quaternary system (AlGaInN), the back barrier layer 22 may have a configuration in which a composition is gradually changed in a thickness direction.

Because the back barrier layer 22 is formed between the buffer layer 21 and the channel layer 23, it is possible to expect an improvement in characteristics such as a suppression of a short channel effect. However, on the other hand, there is a possibility that characteristics deteriorate due to an increase in transition and trap and further, a deterioration in a heat dissipation property. In the present embodiment, a configuration for suppressing the deterioration in the heat dissipation property is provided in the semiconductor stacked section 20. The configuration for suppressing the deterioration in the heat dissipation property will be described in detail later.

The channel layer 23 is a layer configuring a channel of the above-described high electron mobility transistor. The channel layer 23 is a region in which carriers are accumulated by a polarization with the barrier layer 24. The channel layer 23 includes a compound semiconductor material in which the carriers are easily accumulated by the polarization with the barrier layer 24. The compound semiconductor used for the channel layer 23 corresponds to a specific example of a “second compound semiconductor” of the present disclosure. Examples of such a compound semiconductor material include GaN. The channel layer 23 may include an undoped compound semiconductor material. In this case, impurity scattering of the carriers in the channel layer 23 is suppressed, and a carrier movement with a high mobility is achieved. The channel layer 23 forms a two-dimensional electron gas layer 23a that serves as a channel at an interface of the channel layer 23 in contact with the barrier layer 24, by heterojunction of the channel layer 23 and the barrier layer 24 that are formed by different compound semiconductor materials.

The barrier layer 24 includes a compound semiconductor material in which the carriers are accumulated in the channel layer 23 by the polarization with the channel layer 23. Examples of such a compound semiconductor material include Al_{1-c-d}Ga_{c}In_{d}N (0≤c<1, 0≤d<1). The barrier layer 24 may include an undoped compound semiconductor material. In this case, the impurity scattering of the carriers in the channel layer 23 is suppressed, and the carrier movement with the high mobility is achieved. The barrier layer 24 does not necessarily have to be a single layer, and may have a configuration in which a plurality of Al_{1-c-d}Ga_{c}In_{d}N layers that are different from each other in composition ratio are stacked. In a case where the barrier layer 24 is configured by a ternary system (AlInN) or a quaternary system (AlGaInN), the barrier layer 24 may have a configuration in which a composition is gradually changed in a thickness direction.

The semiconductor stacked section 20 further includes, for example, high-concentration impurity regions 25 and 26. The high-concentration impurity regions 25 and 26 correspond to a specific example of a “low resistance material section” of the present disclosure.

The high-concentration impurity region 25 is a region for coupling, with low resistivity, the two-dimensional electron gas layer 23a within the channel layer 23 and a later-described drain electrode 32. The high-concentration impurity region 25 includes a low resistance material having a lower resistance than the channel layer 23, and is in contact with the barrier layer 24, the channel layer 23, and the drain electrode 32. It is preferable that the high-concentration impurity region 25 be formed from a surface of the barrier layer 24 to a region deeper than a region where the two-dimensional electron gas layer 23a is formed in the channel layer 23. However, depending on a configuration of the channel layer 23 and the barrier layer 24, the two-dimensional electron gas layer 23a and the drain electrode 32 may sometimes be coupled to each other with low resistivity even if the high-concentration impurity region 25 is not in direct contact with the two-dimensional electron gas layer 23a. In such a case, the high-concentration impurity region 25 may not be in contact with the two-dimensional electron gas layer 23a.

The high-concentration impurity region 26 is a region for coupling, with low resistivity, the two-dimensional electron gas layer 23a within the channel layer 23 and a later-described source electrode 33. The high-concentration impurity region 26 includes a low resistance material having a lower resistance than the channel layer 23, and is in contact with the barrier layer 24, the channel layer 23, and the source electrode 33. It is preferable that the high-concentration impurity region 26 be formed from a surface of the barrier layer 24 to a region deeper than the region where the two-dimensional electron gas layer 23a is formed in the channel layer 23. However, depending on a configuration of the channel layer 23 and the barrier layer 24, the two-dimensional electron gas layer 23a and the source electrode 33 may sometimes be coupled to each other with low resistivity even if the high-concentration impurity region 25 is not in direct contact with the two-dimensional electron gas layer 23a. In such a case, the high-concentration impurity region 25 may not be in contact with the two-dimensional electron gas layer 23a.

The high-concentration impurity regions 25 and 26 may be formed by performing a selective regrowth that selectively fills the high-concentration impurity regions 25 and 26 on recess sections 20A and 20B formed by etching the semiconductor stacked section 20. The high-concentration impurity regions 25 and 26 may be formed by performing an ion implantation on the semiconductor stacked section 20. In a case where the high-concentration impurity regions 25 and 26 are formed by the above-described selective regrowth, the high-concentration impurity regions 25 and 26 may be formed by, for example, an n-type In₁₋ₑGa_{c}N (0<e<1). At this time, Si or Ge is used as an n-type dopant included in the high-concentration impurity regions 25 and 26, and a concentration (an impurity concentration) of the dopant is, for example, 1×10¹⁸ cm⁻³ or greater.

The high-concentration impurity regions 25 and 26 do not necessarily have to be a single layer, and may have a configuration in which a plurality of n-type In₁₋ₑGa_{c}N layers that are different from each other in composition ratio are stacked. In a case where the high-concentration impurity regions 25 and 26 are configured by a ternary system (InGaN), the high-concentration impurity regions 25 and 26 may have a configuration in which a composition is gradually changed in a thickness direction.

As illustrated in FIG. 1, for example, the recess sections 20A and 20B are formed at the semiconductor stacked section 20 at positions where a later-described gate electrode 34 is sandwiched therebetween. For example, as illustrated in FIG. 2, the recess section 20A is surrounded by the high-concentration impurity region 25 in a plan view. For example, as illustrated in FIG. 2, the recess section 20B is surrounded by the high-concentration impurity region 26 in a plan view. The recess sections 20A and 20B are formed from a surface of the barrier layer 24 to a depth reaching the buffer layer 21. That is, the buffer layer 21 is exposed on bottom surfaces of the recess sections 20A and 20B.

The semiconductor device 1 further includes the gate electrode 34 configuring a gate of the high electron mobility transistor, the drain electrode 32 configuring a drain of the high electron mobility transistor, and the source electrode 33 configuring a source of the high electron mobility transistor. The gate electrode 34 corresponds to a specific example of a “gate electrode” of the present disclosure. The drain electrode 32 corresponds to a specific example of a “drain electrode” of the present disclosure. The source electrode 33 corresponds to a specific example of a “source electrode” of the present disclosure. The drain electrode 32 and the source electrode 33 are formed on the barrier layer 24 at positions sandwiching the gate electrode 34.

A portion of the drain electrode 32 is embedded in the recess section 20A. The portion, of the drain electrode 32, embedded in the recess section 20A corresponds to a specific example of a “low thermal resistance material section having a lower thermal resistance than the channel layer” and a “second low thermal resistance material section”. The portion, of the drain electrode 32, that is embedded inside the recess section 20A is formed directly below a portion, of the drain electrode 32, that is formed on the barrier layer 24. The entire drain electrode 32 may be integrally formed by the same manufacturing process. In addition, the portion, of the drain electrode 32, that is embedded inside the recess section 20A and the portion, of the drain electrode 32, that is formed on the barrier layer 24 may be formed by processes that are different from each other. The portion, of the drain electrode 32, that is embedded in the recess section 20A and the portion, of the drain electrode 32, that is formed on the barrier layer 24 may include the same metal material as each other or may include different metal materials from each other.

A portion of the source electrode 33 is embedded in the recess section 20B. The portion, of the source electrode 33, embedded in the recess section 20B corresponds to a specific example of the “low thermal resistance material section having a lower thermal resistance than the channel layer” and a “first low thermal resistance material section”. The portion, of the source electrode 33, that is embedded inside the recess section 20B is formed directly below a portion, of the source electrode 33, that is formed on the barrier layer 24. The entire source electrode 33 may be integrally formed by the same manufacturing process. In addition, the portion, of the source electrode 33, that is embedded inside the recess section 20B and the portion, of the source electrode 33, that is formed on the barrier layer 24 may be formed by processes that are different from each other. The portion, of the source electrode 33, that is embedded in the recess section 20B and the portion, of the source electrode 33, that is formed on the barrier layer 24 may include the same metal material as each other or may include different metal materials from each other.

The drain electrode 32 and the source electrode 33 are formed from a surface of the barrier layer 24 to a depth reaching the buffer layer 21. That is, the portions, of the drain electrode 32 and the source electrode 33, embedded in the recess sections 20A and 20B penetrate the barrier layer 24, the channel layer 23, and the back barrier layer 22, and are in contact with the buffer layer 21. The portion, of the drain electrode 32, embedded in the recess section 20A is also in contact with the high-concentration impurity region 25 and the channel layer 23. The portion, of the source electrode 33, embedded in the recess section 20B is also in contact with the high-concentration impurity region 26 and the channel layer 23.

The drain electrode 32 is ohmically bonded to the high-concentration impurity region 25. The drain electrode 32 further covers the high-concentration impurity region 25 in plan view and is in contact with an upper surface of the barrier layer 24. The source electrode 33 is ohmically bonded to the high-concentration impurity region 26. The source electrode 33 further covers the high-concentration impurity region 26 in plan view, and is in contact with the upper surface of the barrier layer 24. The drain electrode 32 and the source electrode 33 are, for example, stack bodies in which titanium (Ti), aluminum (Al), nickel (Ni), and gold (Au) are stacked in this order from the substrate 10 in this order to form an ohmic junction with the high-concentration impurity regions 25 and 26. In a case where the drain electrode 32 and the source electrode 33 include the above-described material, it can be said that the drain electrode 32 and the source electrode 33 include the low resistance material having a lower resistance than the channel layer 23, and include a low thermal resistance material having a lower thermal resistance than the channel layer 23.

The gate electrode 34 is formed on the barrier layer 24. The gate electrode 34 is in contact with the upper surface of the barrier layer 24 via a gate opening 31A formed on an insulating layer 31 covering the upper surface of the semiconductor stacked section 20. The insulating layer 31 is a layer that has an insulating property with respect to the barrier layer 24 and protects the barrier layer 24 from impurities such as ions. The insulating layer 31 further includes a material that forms a good interface with the barrier layer 24 and does not deteriorate device characteristics. The insulating layer 31 is configured by, for example, aluminum oxide (Al₂O₃), silicon oxide (SiO₂), silicon nitride (SiN), or a stack body thereof.

### [Manufacturing Method]

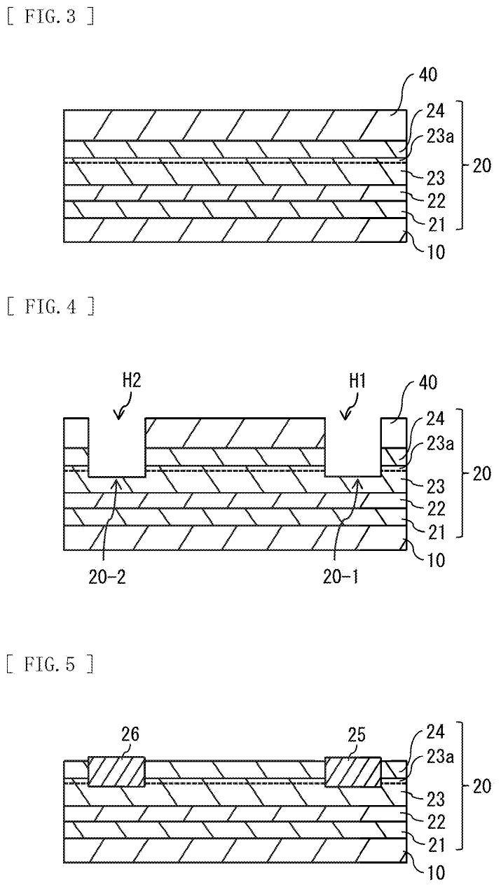

Next, a method of manufacturing the semiconductor device 1 will be described with reference to FIGS. 3 to 9. FIGS. 3 to 9 illustrate an example of a cross-sectional configuration of a wafer in a manufacturing process of the semiconductor device 1.

In order to manufacture the semiconductor device 1, a compound semiconductor is collectively formed on the substrate 10 by an epitaxial crystalline growth method such as MOCVD (Metal Organic Chemical Vapor Deposition: metal organic vapor phase deposition) method. At this time, for example, trimethylgallium ((CH₃)₃Ga) is used as a raw material gas of gallium, for example, trimethylaluminum ((CH₃)₃Al) is used as a raw material gas of aluminum, and trimethylindium ((CH₃)₃In) is used as a raw material gas of indium. In addition, ammonia (NH₃) is used as a raw material gas of nitrogen. Further, for example, monosilane (SiH₄) is used as a raw material gas of silicon. As a result, the buffer layer 21 to the barrier layer 24 (the semiconductor stacked section 20) are formed on the substrate 10 (FIG. 3). Thereafter, the insulating layer 40 is formed on the surface of the barrier layer 24 (FIG. 3).

Next, openings H1 and H2 are formed on regions, of the insulating layer 40, where the high-concentration impurity regions 25 and 26 are to be formed (FIG. 4). Subsequently, etching is selectively performed by a RIE method using a chlorine-based gas and using the insulating layer 40 as a mask until reaching the channel layer 23, whereby the recess sections 20-1 and 20-2 are formed in the semiconductor stacked section 20 (FIG. 4). Next, the high-concentration impurity regions 25 and 26 are so formed as to embed the recess sections 20-1 and 20-2 (FIG. 5). Thereafter, the insulating layer 40 is removed (FIG. 5).

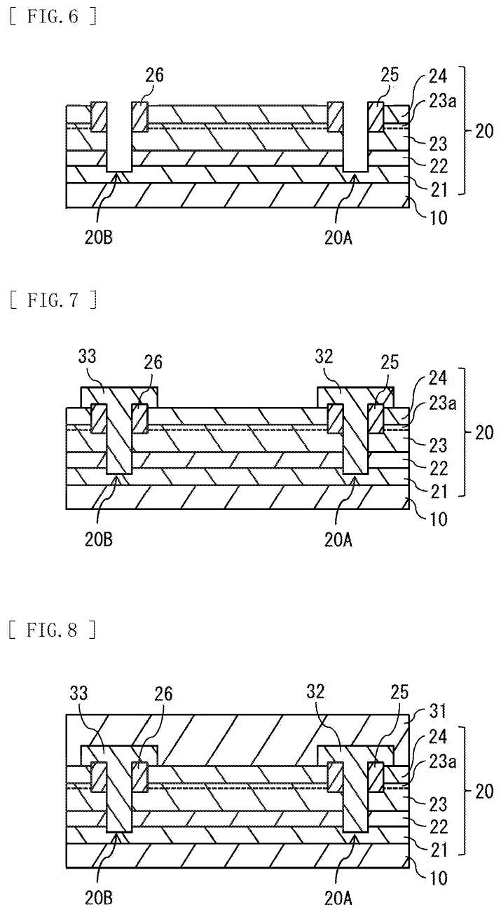

Next, an insulating layer is formed over the entire surface, following which openings are formed in regions, of the insulating layer, where the recess sections 20A and 20B are to be formed. At this time, the high-concentration impurity regions 25 and 26 are exposed on bottom surfaces of the openings. Subsequently, etching is selectively performed by a RIE method using a chlorine-based gas and using the insulating layer as a mask until reaching the buffer layer 21, whereby the recess sections 20A and 20B are formed in the semiconductor stacked section 20 (FIG. 6). At this time, the recess sections 20A and 20B are so formed as to penetrate through the high-concentration impurity regions 25 and 26, the channel layer 23, and the back barrier layer 22.

Next, the drain electrode 32 and the source electrode 33 are formed by, for example, a vacuum deposition method or a sputtering method (FIG. 7). At this time, the drain electrode 32 and the source electrode 33 are so formed as to embed the recess sections 20A and 20B and cover the high-concentration impurity regions 25 and 26. Next, for example, the insulating layer 31 is formed over the entire surface including the drain electrode 32 and the source electrode 33 (FIG. 8). Next, the gate opening 31A is formed in a region, of the insulating layer 31, where the gate electrode 34 is to be formed (FIG. 9). At this time, the barrier layer 24 is exposed on a bottom surface of the gate opening 31A. Subsequently, the gate electrode 34 is formed by, for example, a vacuum deposition method or a sputtering method (FIG. 1). At this time, the gate opening 31A is so formed as to embed the gate electrode 34 and as to have a T-shaped cross section. The semiconductor device 1 is thus manufactured.

### Effects

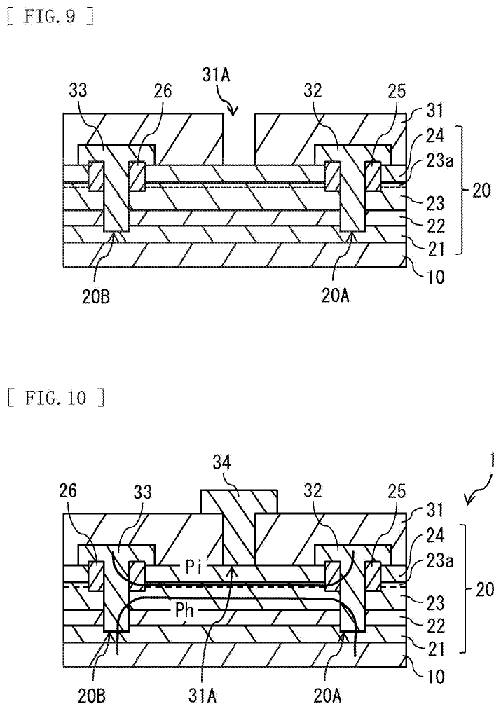

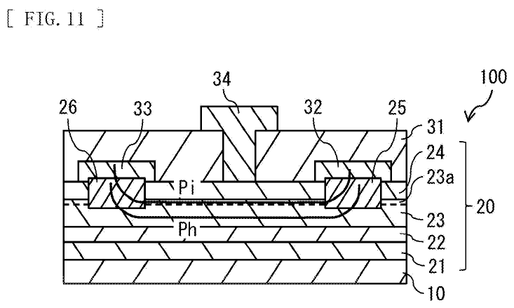

Next, effects of the semiconductor device 1 will be described in comparison with a comparative example. FIG. 10 illustrates an example of a current path Pi and a heat dissipation path Ph of the semiconductor device 1. FIG. 11 illustrates an example of a current path Pi and a heat dissipation path Ph of a semiconductor device 100 according to the comparative example.

In the semiconductor device 1, a current flows from the drain electrode 32 to the source electrode 33 through the current path Pi including the two-dimensional electron gas layer 23a of the channel layer 23. At this time, a heat generated in the channel layer 23 is discharged to the drain electrode 32 side and the source electrode 33 side via the same path as the current path Pi. The heat generated in the channel layer 23 is further discharged to the substrate 10 side through the heat dissipation path P2 including the portion, of the drain electrode 32, that is embedded in the recess section 20A and the portion, of the source electrode 33, that is embedded in the recess section 20B.

In general, the back barrier layer 22 includes a material (a ternary system (AlInN) or a quaternary system (AlGaInN)) having a lower thermal conductivity than the channel layer 23 or the like. Accordingly, in the semiconductor device 100 according to the comparative example, the discharge of the heat generated in the channel layer 23 to the substrate 10 side is inhibited by the back barrier layer 22. In the semiconductor device 100 according to the comparative example, the heat generated in the channel layer 23 is mainly discharged to the drain electrode 32 side and the source electrode 33 side, and is hardly discharged to the substrate 10 side. As a result, in the semiconductor device 100 according to the comparative example, it is not possible to sufficiently discharge the heat generated in the channel layer 23, and the channel layer 23 and its vicinity become high in temperature, resulting in deterioration in characteristics.

In contrast, in the semiconductor device 1, the heat dissipation path P2 is provided to penetrate through the back barrier layer 22 and is coupled to the buffer layer 21. Accordingly, the discharge of the heat generated in the channel layer 23 toward the substrate 10 side is not obstructed by the back barrier layer 22. Thus, in the semiconductor device 1, the heat generated in the channel layer 23 is discharged not only to the drain electrode 32 side and the source electrode 33 side but also to the substrate 10 side. As a result, it is possible to lower the temperature of the channel layer 23 and the vicinity thereof, and to suppress the generation of the characteristic deterioration.

### 2. MODIFICATION EXAMPLES

Next, modification examples of the semiconductor device 1 according to the above-described embodiment will be described.

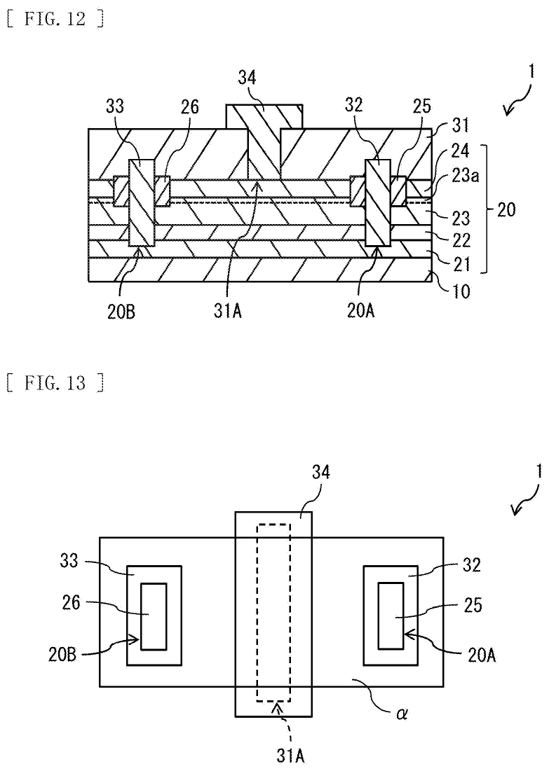

FIG. 12 illustrates a modification example of a cross-sectional configuration of the semiconductor device 1 according to the embodiment described above. FIG. 13 illustrates an example of a top surface configuration of the semiconductor device 1 of FIG. 12.

In the above embodiment, the drain electrode 32 and the source electrode 33 are so formed as to be in contact with the upper surface of the barrier layer 24. At this time, it is possible to discharge a portion of the heat generated in the channel layer 23 from the upper surface of the barrier layer 24 to the substrate 10 side via the drain electrode 32 and the source electrode 33. However, in a case where there is no problem even if this heat discharge path is eliminated, it is possible to eliminate the heat discharge path. At this time, the drain electrode 32 and the source electrode 33 may have a rod-like shape so as not to be in contact with the upper surface of the barrier layer 24, for example, as illustrated in FIGS. 12 and 13.

### 4. APPLICATION EXAMPLES

### Application Example 1

Next, with reference to FIG. 14, a high-frequency module 2 to which the semiconductor device 1 according to an embodiment of the present disclosure and a modification example thereof is applied will be described. The high-frequency module 2 corresponds to a specific example of a “semiconductor module” of the present disclosure. FIG. 14 is a perspective view of the high-frequency module 2.

The high-frequency module 2 includes, for example, an edge antenna 42, a driver 43, a phase adjustment circuit 44, a switch 41, a low-noise amplifier 45, a bandpass filter 46, and a power amplifier 47.

The high-frequency module 2 is an antenna-integrated module in which the edge antenna 42 formed in an array shape and front-end components including, for example, the switch 41, the low-noise amplifier 45, the bandpass filter 46, and the power amplifier 47 are integrally mounted as a single module. Such a high-frequency module 2 may be used, for example, as a transceiver for communication. Transistors included in the switch 41, the low-noise amplifier 45, the power amplifier 47, and the like included in the high-frequency module 2 each may be configured by, for example, the high electron mobility transistor provided in the semiconductor device 1 according to the embodiment of the present disclosure and the modification example thereof in order to increase a gain with respect to a high frequency.

### Application Example 2

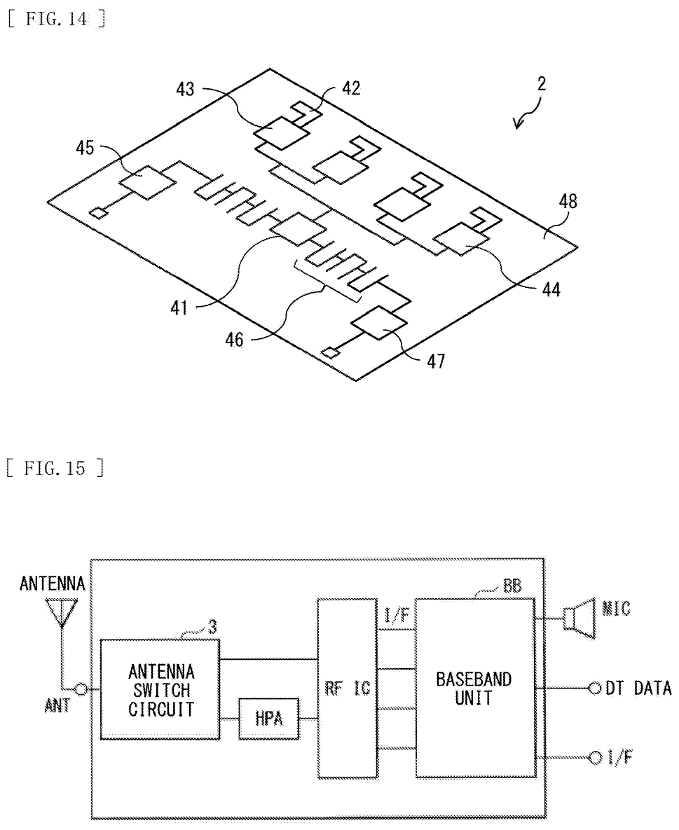

FIG. 15 illustrates an example of a wireless communication device. The wireless communication device corresponds to a specific example of an “electronic apparatus” of the present disclosure. The wireless communication device is, for example, a mobile telephone system having a multifunctional function such as voice, data communication, or LAN access. The wireless communication device includes, for example, an antenna ANT, an antenna switch circuit 3, a high-power amplifier HPA, a high-frequency integrated circuit RFIC (Radio Frequency Integrated Circuit), a baseband unit BB, an audio output unit MIC, a data output unit DT, and an interface unit I/F (for example, a wireless LAN (W-LAN: Wireless Local Area Network), Bluetooth (registered trademark), etc.). The antenna switch circuit 3 includes the high electron mobility transistor provided in the semiconductor device 1 according to an embodiment of the present disclosure and the modification example thereof. The high-frequency integrated circuit RFIC and the baseband unit BB are coupled by the interface unit I/F.

In the wireless communication device, at the time of transmission, that is, in a case where a transmission signal is to be outputted from a transmission system of the wireless communication device to the antenna ANT, a transmission signal outputted from the baseband unit BB is outputted to the antenna ANT via the high-frequency integrated circuit RFIC, the high-power amplifier HPA, and the antenna switch circuit 3.

At the time of reception, that is, in a case where a signal received by the antenna ANT is to be inputted to a reception system of the wireless communication device, the reception signal is inputted to the baseband unit BB via the antenna switch circuit 3 and the high-frequency integrated circuit RFIC. A signal processed by the baseband unit BB is outputted from an output unit such as the audio output unit MIC, the data output unit DT, or the interface unit I/F.

Although the present disclosure has been described with reference to the embodiments, modification examples, and application examples, the present disclosure is not limited to the above-described embodiments and the like, and various modifications are possible. It should be noted that the effects described in this specification are only exemplified. Effects of the present disclosure are not limited to the effects described herein. The present disclosure may have effects other than the effects described herein.

For example, the present disclosure may also be configured as follows.

(1)

A semiconductor device including:
a semiconductor layer;
a channel layer including a semiconductor material different from that of the semiconductor layer, and stacked on the semiconductor layer;
a buffer layer formed between the semiconductor layer and the channel layer;
a barrier layer formed on the channel layer;
a gate electrode formed on the barrier layer;
a source electrode and a drain electrode formed on the barrier layer at positions sandwiching the gate electrode;
a low resistance material section having a lower resistance than the channel layer, and in contact with the barrier layer, the channel layer, and the source electrode or the drain electrode; and
a low thermal resistance material section having a lower thermal resistance than the channel layer, and in contact with the channel layer and the buffer layer.
   (2)

The semiconductor device according to (1), in which the low thermal resistance material section includes a metal material that penetrates the barrier layer and the channel layer.

(3)

The semiconductor device according to (2), in which the low thermal resistance material section is formed in contact with the source electrode or the drain electrode, and formed directly below the source electrode or the drain electrode.

(4)

The semiconductor device according to (2) or (3), in which the low thermal resistance material section and the low resistance material section are ohmic-bonded to each other.

(5)

The semiconductor device according to any one of (2) to (4), further including a back barrier layer formed between the channel layer and the buffer layer and having a wider bandgap than the channel layer, in which
the low thermal resistance material section includes a metal material that penetrates the buffer layer, the channel layer, and the back barrier layer.
   (6)

The semiconductor device according to (3), in which the low thermal resistance material section includes:
a first low thermal resistance material section formed in contact with the source electrode and formed directly below the source electrode; and
a second low thermal resistance material section formed in contact with the drain electrode and formed directly below the drain electrode.
   (7)

The semiconductor device according to (6), in which
the source electrode includes the same metal material as the first low thermal resistance material section, and is formed integrally with the first low thermal resistance material section, and
the drain electrode includes the same metal material as the second low thermal resistance material section, and is formed integrally with the second low thermal resistance material section.
   (8)

The semiconductor device according to any one of (1) to (7), in which
the channel layer includes GaN, and
the barrier layer includes Al_{1-x-y}GaₓIn_{y}N, where 0≤x<1 and 0≤y<1.
   (9)

A semiconductor module including:
a semiconductor layer;
a channel layer including a semiconductor material different from that of the semiconductor layer, and stacked on the semiconductor layer;
a buffer layer formed between the semiconductor layer and the channel layer;
a barrier layer formed on the channel layer;
a gate electrode formed on the barrier layer;
a source electrode and a drain electrode formed on the barrier layer at positions sandwiching the gate electrode;
a low resistance material section having a lower resistance than the channel layer, and in contact with the barrier layer, the channel layer, and the source electrode or the drain electrode; and
a low thermal resistance material section having a lower thermal resistance than the channel layer, and in contact with the channel layer and the buffer layer.
   (10)

An electronic apparatus including:
a semiconductor layer;
a channel layer including a semiconductor material different from that of the semiconductor layer, and stacked on the semiconductor layer;
a buffer layer formed between the semiconductor layer and the channel layer;
a barrier layer formed on the channel layer;
a gate electrode formed on the barrier layer;
a source electrode and a drain electrode formed on the barrier layer at positions sandwiching the gate electrode;
a low resistance material section having a lower resistance than the channel layer, and in contact with the barrier layer, the channel layer, and the source electrode or the drain electrode; and
a low thermal resistance material section having a lower thermal resistance than the channel layer, and in contact with the channel layer and the buffer layer.

In the semiconductor device, the semiconductor module, and the electronic apparatus according to one embodiment of the present disclosure, the low thermal resistance material section is in contact with the buffer layer, formed between the semiconductor layer and the channel layer, and the channel layer. Thus, it is possible to discharge the heat generated in the channel layer to the semiconductor layer side through the low thermal resistance material section. Hence, it is possible to achieve a semiconductor device having a higher heat dissipation property as compared with a case where the heat generated in the channel layer is discharged only to the source electrode side and the drain electrode side. It should be noted that effects of the present disclosure are not necessarily limited to the effects described herein, and may be any of the effects described in this specification.

The present application claims the benefit of Japanese Priority Patent Application JP2021-014618 filed with the Japan Patent Office on Feb. 1, 2021, the entire contents of which are incorporated herein by reference.

It should be understood by those skilled in the art that various modifications, combinations, sub-combinations and alterations may occur depending on design requirements and other factors insofar as they are within the scope of the appended claims or the equivalents thereof.

1. A semiconductor device comprising:
a semiconductor layer;
a channel layer including a semiconductor material different from that of the semiconductor layer, and stacked on the semiconductor layer;
a buffer layer formed between the semiconductor layer and the channel layer;
a barrier layer formed on the channel layer;
a gate electrode formed on the barrier layer;
a source electrode and a drain electrode formed on the barrier layer at positions sandwiching the gate electrode;
a low resistance material section having a lower resistance than the channel layer, and in contact with the barrier layer, the channel layer, and the source electrode or the drain electrode; and
a low thermal resistance material section having a lower thermal resistance than the channel layer, and in contact with the channel layer and the buffer layer.

2. The semiconductor device according to claim 1, wherein the low thermal resistance material section includes a metal material that penetrates the barrier layer and the channel layer.

3. The semiconductor device according to claim 2, wherein the low thermal resistance material section is formed in contact with the source electrode or the drain electrode, and formed directly below the source electrode or the drain electrode.

4. The semiconductor device according to claim 2, wherein the low thermal resistance material section and the low resistance material section are ohmic-bonded to each other.

5. The semiconductor device according to claim 2, further comprising a back barrier layer formed between the channel layer and the buffer layer and having a wider bandgap than the channel layer, wherein
the low thermal resistance material section includes a metal material that penetrates the buffer layer, the channel layer, and the back barrier layer.

6. The semiconductor device according to claim 3, wherein the low thermal resistance material section includes:
a first low thermal resistance material section formed in contact with the source electrode and formed directly below the source electrode; and
a second low thermal resistance material section formed in contact with the drain electrode and formed directly below the drain electrode.

7. The semiconductor device according to claim 6, wherein
the source electrode includes a same metal material as the first low thermal resistance material section, and is formed integrally with the first low thermal resistance material section, and
the drain electrode includes a same metal material as the second low thermal resistance material section, and is formed integrally with the second low thermal resistance material section.

8. The semiconductor device according to claim 1, wherein
the channel layer includes GaN, and
the barrier layer includes Al_{1-x-y}GaₓIn_{y}N, where 0≤x<1 and 0≤y<1.

9. A semiconductor module comprising:
a semiconductor layer;
a channel layer including a semiconductor material different from that of the semiconductor layer, and stacked on the semiconductor layer;
a buffer layer formed between the semiconductor layer and the channel layer;
a barrier layer formed on the channel layer;
a gate electrode formed on the barrier layer;
a source electrode and a drain electrode formed on the barrier layer at positions sandwiching the gate electrode;
a low resistance material section having a lower resistance than the channel layer, and in contact with the barrier layer, the channel layer, and the source electrode or the drain electrode; and
a low thermal resistance material section having a lower thermal resistance than the channel layer, and in contact with the channel layer and the buffer layer.

10. An electronic apparatus comprising:
a semiconductor layer;
a channel layer including a semiconductor material different from that of the semiconductor layer, and stacked on the semiconductor layer;
a buffer layer formed between the semiconductor layer and the channel layer;
a barrier layer formed on the channel layer;
a gate electrode formed on the barrier layer;
a source electrode and a drain electrode formed on the barrier layer at positions sandwiching the gate electrode;
a low resistance material section having a lower resistance than the channel layer, and in contact with the barrier layer, the channel layer, and the source electrode or the drain electrode; and
a low thermal resistance material section having a lower thermal resistance than the channel layer, and in contact with the channel layer and the buffer layer.
